(19) United States
(12) Patent Application Publication
(10) Pub. No.: US 2024/0291232 A1
(43) Pub. Date: Aug. 29, 2024

(54) MULTI-FLUID HEAT EXCHANGER FOR A LASER SYSTEM

(71) Applicant: Applied Research Associates, Inc., Albuquerque, NM (US)

(72) Inventors: Christopher Scott Church, Panama City, FL (US); Sebastian MacNamara, Panama City Beach, FL (US)

(21) Appl. No.: 18/175,209

(22) Filed: Feb. 27, 2023

(51) Int. Cl. H01S 5/024

(52) U.S. Cl. CPC H01S 5/02423

(57) ABSTRACT

A method, system, and computer-readable media for cooling a laser system using a heat exchanger system containing one or more phase change materials operable to absorb heat from a coolant circulated from the laser system. The phase change material absorbs heat during phase change in the form of latent heat energy to thereby cool the coolant. The heat exchanger further includes one or more fans to provide air cooling to cool the phase change material back to an initial phase.

### RELATED APPLICATIONS

This patent application shares certain subject matter in common with earlier-filed U.S. Provisional Patent Application No. 62/690,067, filed Jun. 26, 2018, and U.S. Pat. No. 10,900,755, filed Jun. 21, 2019, both of which are entitled LASER WEAPON SYSTEM. The above-referenced patent application and patent are hereby incorporated by reference in their entirety into the present application.

### BACKGROUND

### 1. Field

Embodiments of the invention relate to laser system cooling. More specifically, embodiments of the invention relate to laser system cooling using phase change materials.

### 2. Related Art

In some circumstances, heat exchangers are paired with laser generation systems to draw heat away from the laser generation system and prevent overheating. The heat exchangers typically include or are coupled to a chiller. The chiller increases the overall weight and size footprint of the heat exchanger but allows the laser generation system to operate in relatively high temperature environments. In some cases, the inclusion of the chiller makes it difficult to produce a portable laser system heat exchanger that is capable of being carried by a single user.

### SUMMARY

Embodiments of the invention solve the above-mentioned problems by providing a chiller-less heat exchanger system configured to be coupled to a laser system. The heat exchanger system includes a heat exchanger containing one or more phase change materials (PCMs) that absorb heat from a coolant cycled from the laser system. One or more fans are coupled to the heat exchanger to enhance a heat transfer rate between the PCM and the ambient environment to thereby reduce a freezing time of the PCM. The one or more fans allow the laser system to operate in environments of relatively higher temperatures without a significant weight increase as compared to the chiller systems described above.

In some aspects, the techniques described herein relate to a multi-fluid heat exchanger configured to be coupled to a laser system, the multi-fluid heat exchanger including a rigid housing, a repeating fin structure disposed within the rigid housing, the repeating fin structure including a plurality of coolant channels receiving coolant from the laser system, a plurality of phase change material (PCM) channels containing one or more PCMs, wherein the one or more PCMs absorb heat from the coolant and are selected to melt at or below an operating temperature of the laser system and to freeze at or above an ambient air temperature, and a plurality of air channels receiving air to cool the one or more PCMs, and one or more fans mounted onto the rigid housing that circulate air through the plurality of air channels to increase a cooling rate of the one or more PCMs.

In some aspects, the techniques described herein relate to a multi-fluid heat exchanger, wherein the plurality of coolant channels are oriented in a first direction.

In some aspects, the techniques described herein relate to a multi-fluid heat exchanger, wherein the plurality of PCM channels and the plurality of air channels are oriented in a second direction perpendicular to the first direction.

In some aspects, the techniques described herein relate to a multi-fluid heat exchanger, wherein the laser system is a laser weapon system that circulates the coolant to cool a laser generation module of the laser weapon system.

In some aspects, the techniques described herein relate to a multi-fluid heat exchanger, wherein the one or more PCMs includes an organic PCM.

In some aspects, the techniques described herein relate to a multi-fluid heat exchanger, further including one or more PCM sensors disposed in the plurality of PCM channels, the one or more PCM sensors operable to detect a percentage of the one or more PCMs that is melted.

In some aspects, the techniques described herein relate to a multi-fluid heat exchanger, wherein a notification is transmitted responsive to detecting the percentage of the one or more PCMs that is melted using the one or more PCM sensors if the percentage of the one or more PCMs that is melted is above a predetermined threshold.

In some aspects, the techniques described herein relate to a heat exchanger system configured to be coupled to a laser system, the heat exchanger system including a heat exchanger having a rigid housing and a repeating fin structure disposed in the rigid housing, the repeating fin structure including a plurality of coolant channels receiving coolant from the laser system, and a plurality of phase change material (PCM) channels containing one or more PCMs, wherein the one or more PCMs absorb heat from the coolant and are selected to melt across an operating temperature range of the laser system and to freeze at or above an ambient air temperature, one or more fans coupled to the heat exchanger and configured to cool the one or more PCMs, and one or more radiators coupled to the heat exchanger and configured to cool the coolant.

In some aspects, the techniques described herein relate to a heat exchanger system, wherein the one or more fans and the one or more radiators are physically separate from the heat exchanger.

In some aspects, the techniques described herein relate to a heat exchanger system, further including one or more pumps circulating the coolant through the plurality of coolant channels and the one or more radiators, wherein the one or more pumps are activated based on a comparison between a temperature of the one or more PCMs and a temperature of the laser system.

In some aspects, the techniques described herein relate to a heat exchanger system, wherein the plurality of PCM channels includes a first PCM compartment storing a first PCM, wherein the first PCM is melted at a first temperature within the operating temperature range of the laser system, and a second PCM compartment storing a second PCM, wherein the second PCM is melted at a second temperature that is above the first temperature and within the operating temperature range of the laser system.

In some aspects, the techniques described herein relate to a heat exchanger system, wherein the heat exchanger is removable from the heat exchanger system such that the heat exchanger may be replaced based on the ambient air temperature.

In some aspects, the techniques described herein relate to a heat exchanger system, further including a removable auxiliary chiller configured to further cool the one or more PCMs if an increased ambient air temperature condition is reached.

In some aspects, the techniques described herein relate to a heat exchanger system, further including a battery coupled to the one or more fans, the battery operable to provide electrical power to the one or more fans.

In some aspects, the techniques described herein relate to a multi-fluid heat exchanger configured to be coupled to a laser system, the multi-fluid heat exchanger including a rigid housing, a repeating fin structure disposed within the rigid housing, the repeating fin structure including a plurality of coolant channels receiving coolant from the laser system, a plurality of phase change material (PCM) channels containing one or more PCMs, wherein the one or more PCMs absorb heat from the coolant and are selected to melt at or below an operating temperature of the laser system and to freeze at or above an ambient air temperature, and a plurality of air channels receiving air to cool the one or more PCMs.

In some aspects, the techniques described herein relate to a multi-fluid heat exchanger, further including one or more fans mounted onto the rigid housing that circulate air through the plurality of air channels to increase a cooling rate of the one or more PCMs.

In some aspects, the techniques described herein relate to a multi-fluid heat exchanger, further including a controller programmed to receive a first signal indicative of a temperature of the one or more PCMs, receive a second signal indicative of an ambient temperature, compare the temperature of the one or more PCMs and the ambient temperature, and increase a fan speed of the one or more fans based on comparing the temperature of the one or more PCMs and the ambient temperature.

In some aspects, the techniques described herein relate to a multi-fluid heat exchanger, further including one or more thermoelectric devices configured to absorb waste heat from the laser system and generate electrical energy, wherein the electrical energy generated by the one or more thermoelectric devices is used to at least partially power the one or more fans.

In some aspects, the techniques described herein relate to a multi-fluid heat exchanger, further including one or more plates including an aluminum material disposed on a bottom surface of the rigid housing adjacent to the plurality of PCM channels, the one or more plates configured to increase heat transfer between a surrounding environment and the one or more PCMs.

In some aspects, the techniques described herein relate to a multi-fluid heat exchanger, further including a radiator portion disposed between a fluid connection of the multi-fluid heat exchanger and the laser system, the radiator portion configured to cool the coolant.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the invention will be apparent from the following detailed description of the embodiments and the accompanying drawing figures.

### BRIEF DESCRIPTION OF THE DRAWING FIGURES

Embodiments of the invention are described in detail below with reference to the attached drawing figures, wherein:

FIG. 1 illustrates an exemplary heat exchanger system relating to some embodiments;

FIG. 2A illustrates a partially exploded view of an exemplary three-fluid heat exchanger relating to some embodiments;

FIG. 2B illustrates a repeating fin structure separated from the three-fluid heat exchanger relating to some embodiments;

FIG. 3 illustrates an exemplary control system relating to some embodiments; and

FIG. 4 illustrates an exemplary method of operation for the heat exchanger system relating to some embodiments.

The drawing figures do not limit the invention to the specific embodiments disclosed and described herein. The drawings are not necessarily to scale, emphasis instead being placed upon clearly illustrating the principles of the invention.

### DETAILED DESCRIPTION

The following detailed description references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the invention. The following detailed description is, therefore, not to be taken in a limiting sense. The scope of the invention is defined only by the appended claims, along with the full scope of equivalents to which such claims are entitled.

In this description, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments but is not necessarily included. Thus, the technology can include a variety of combinations and/or integrations of the embodiments described herein.

Previous laser system heat exchangers use a chiller to provide cooling to increase a rate at which heat is exhausted from the system. However, the chiller provides additional weight and occupies significant volume, which reduces the ease of creating a fully portable system. For example, operators of the laser system may be burdened with carrying a separate chiller component or another operator may be tasked with carrying the chiller such that it takes two or more operators to operate a single laser system. Accordingly, embodiments are contemplated in which the chiller is removed from the heat exchanger portion of a laser system. As such, the overall size of the heat exchanger portion is reduced without a significant reduction in the efficiency of the system. The laser system and heat exchanger are operable to be transported by a single operator without a significant weight burden.

### System and Form Factor

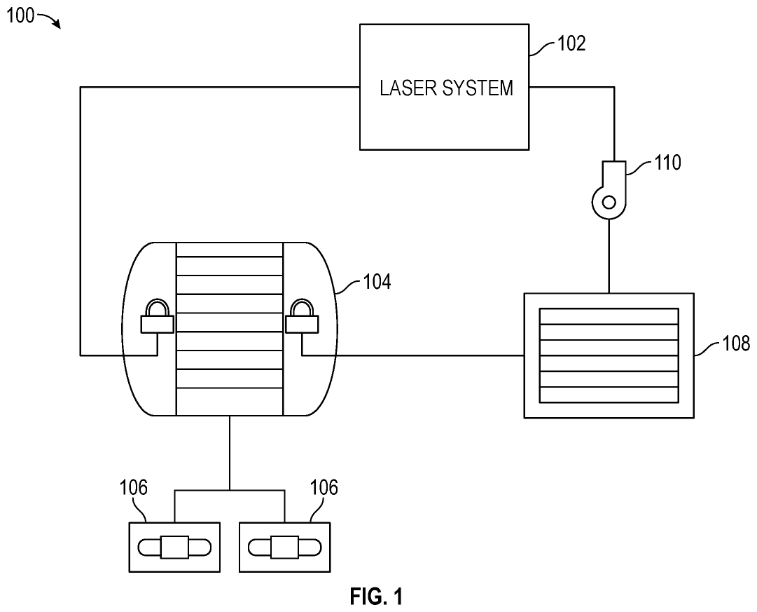

FIG. 1 illustrates an exemplary heat exchanger system 100 relating to some embodiments. In some such embodiments, the heat exchanger system 100 is configured to be coupled to a laser system 102, as shown. Accordingly, the heat exchanger system 100 may be used to provide cooling to the laser system 102 to reduce heating of the laser system 102. The laser system 102 may be any laser generation module, such as a laser weapon system, a laser-based manufacturing tool or device, a laser-based medical device, or another type of laser system not explicitly disclosed herein. In some embodiments, the laser system 102 comprises a solid-state laser generation system. Examples of laser weapon systems include any of counter-explosive applications, such as detonation of unexploded ordinance (UXO), improvised explosive devices (IEDs), or mines, counter-infrastructure applications, such as destroying target communications systems, cameras, power systems, radar, lights, power systems, or locks, and counter-moving-target applications, such as incapacitating or destroying airborne, terrestrial, or maritime unmanned drones. However, it should be understood that the heat exchanger system 100 may be coupled to any of a variety of other laser system applications not explicitly described herein.

In some embodiments, the heat exchanger system 100 includes a heat exchanger 104, as shown. The heat exchanger 104 may be a multi-fluid heat exchanger configured to accommodate a number of different fluids and facilitate heat exchange between said fluids. For example, in some embodiments, any combination of air, coolant, and phase change material (PCM) may be included within the heat exchanger 104. In some embodiments, the heat exchanger 104 receives a coolant from the laser system 102. The coolant may be any of a variety of different heat exchange fluids. For example, the heat exchange fluid may include any combination of alcohol or water-based coolants, such as, water, deionized water, glycol, glycol/water solutions, and dielectric fluids. In some embodiments, a liquid coolant is selected such that the coolant may be pumped between the heat exchanger 104 and the laser system 102. In some embodiments, the coolant is circulated through a laser system heat exchanger included on the laser system 102 to cool a laser generation portion of the laser system 102. For example, the coolant may be configured to cool a plurality of laser diodes and/or other components of the laser system 102 that heat up during operation.

PCM refers to any of a number of different materials characterized by the ability to absorb/release substantially large amounts of energy during a change of state or “phase”. In some cases, the energy stored or released during phase change is referred to as “latent heat”. In some embodiments, the heat exchanger 104 includes a plurality of fluid channels for containing the heat exchange fluids, as will be described in further detail below.

The heat exchanger system 100 may include additional components for increasing the heat exchange rate. For example, in some embodiments, the heat exchanger system 100 includes one or more fans 106, as shown. The fans 106 may be incorporated into the heat exchanger 104 and configured to circulate air through the heat exchanger 104. Alternatively, or additionally, the one or more fans 106 may include at least one fan 106 disposed in a separate compartment. In some embodiments, the one or more fans 106 may include any of variety of different types of fans such as blowers, radial fans, computer fans, and other suitable types of fans.

In some cases, the one or more fans 106 are operable to increase a cooling rate and overall cooling speed of a PCM disposed within the heat exchanger 104. For example, the one or more fans 106 may increase a heat transfer rate between the PCM and the ambient air by way of convection such that a portion of melted PCM is frozen to a solid phase. In some embodiments, the cooling speed refers to the rate at which the PCM is frozen after being melted such that the PCM becomes available to absorb additional heat from the coolant in a subsequent phase change cycle. Further, the system including the one or more fans 106 is substantially lighter and consumes far less power when compared to similar systems that include a chiller. Specifically, the fans may increase the heat transfer rate without significantly affecting the overall weight of the heat exchanger 104.

The heat exchanger system 100 may further include at least one radiator 108, as shown. In some embodiments, the radiator 108 may be configured to cool the coolant circulated through the heat exchanger 104. The radiator 108 may be incorporated into the heat exchanger 104 or may be included physically separate such that the coolant is circulated to the radiator through piping or other fluid transport means. In some embodiments, one or more pumps 110 may be included in the heat exchanger system 100. For example, a pump 110 may be disposed in a fluid path of the coolant between the radiator 108 and the laser system 102, as shown. However, it should be understood that the one or more pumps may additionally or alternatively be disposed elsewhere in the fluid path of the coolant. Accordingly, the one or more pumps 110 may be configured to circulate the coolant through any of the heat exchanger 104, the laser system 102, and the radiator 108. Additionally, or alternatively, the one or more pumps 110 may be incorporated into any of said components. For example, a pump 110 may be included in the laser system 102 to circulate the coolant through the laser system 102 and externally.

In some embodiments, one or more batteries or other power sources may be included within the heat exchanger system 100. For example, in some embodiments, a first and second battery may be included within the laser system 102 to provide power to the laser system 102 and a third battery may be included within or coupled to the heat exchanger 104 to provide power, for example, to the one or more fans 106 and the one or more pumps 110. Alternatively, or additionally, in some embodiments, a power source may be shared between the laser system 102 and the heat exchanger 104.

In some embodiments, the heat exchanger 104 may be integrated directly into the laser system 102. For example, the heat exchanger 104 may replace the laser system heat exchanger of the laser system 102. In some such embodiments, the heat exchanger 104 may be incorporated into a housing of the laser system 102. Embodiments are contemplated in which components of the laser system 102 may be mounted directly onto the heat exchanger 104 such that the components are cooled by the heat exchanger 104. For example, one or more laser diodes of the laser system 102 may be mounted onto a housing or other portion of the heat exchanger 104. The heat exchanger 104, as described above, may include a multifluid heat exchanger that circulates a plurality of fluids for cooling the laser system 102. As such, in some embodiments, each of PCMs, a coolant, and ambient air may be used to cool the laser system 102 from a heat exchanger disposed within or on a housing of the laser system 102.

In some embodiments, a geometry and/or size of the heat exchanger 104 may be modified such that the heat exchanger 104 is able to be disposed within the laser system 102 such as on or within a housing of the laser system 102. Accordingly, the overall size of the laser system and heat exchanger system 100 is reduced by directly integrating the heat exchanger 104 into the laser system 102. In some such embodiments, the heat exchanger 104 may be curved or angled, for example, to cover a portion of the laser system 102. Embodiments are contemplated in which the heat exchanger 104 is curved with a cylindrical geometry that surround at least a portion of the laser system 102 to increase heat transfer with the surrounding environment. In some such embodiments, the cylindrical geometry maximizes a surface area of the heat exchanger 104 that is exposed to the ambient environment to thereby increase heat transfer. Additionally, or alternatively, the heat exchanger 104 may be disposed on a top portion, a side portion, or another suitable location on the laser system 102. Further, a variety of additional geometries of the heat exchanger 104 not explicitly described herein are also contemplated.

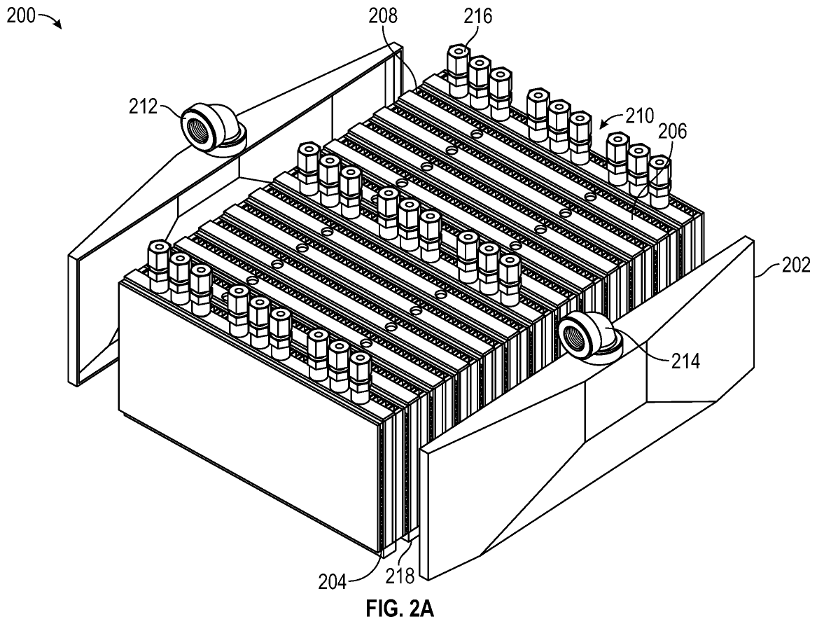

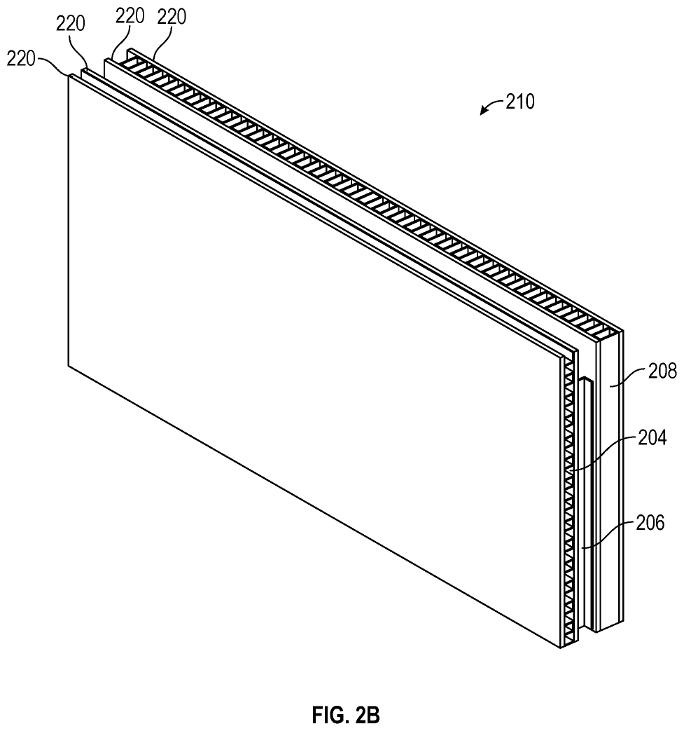

FIG. 2A illustrates a partially exploded view of an exemplary three-fluid heat exchanger 200 relating to some embodiments. The three-fluid heat exchanger 200 may include a housing 202, which may be a rigid structure supporting the components of the three-fluid heat exchanger 200. FIG. 2A shows the side portions of the housing 202 exploded from an inner portion of the housing 202; however, it should be understood that, during use, in some embodiments, the side portions may be placed directly onto the inner portion and may be removably or permanently secured to the inner portion. In some embodiments, the housing 202 may include any of a number of rigid materials, such as any combination of aluminum or aluminum alloys, copper or copper alloys, hard plastic, or other suitable rigid materials. In some such embodiments, materials with a high thermal conductivity may be selected to provide additional heat transfer for the three-fluid heat exchanger 200, such as aluminum, or copper. Additionally, portions of the housing may be doped with additional materials to further increase the thermal conductivity. For example, aluminum may be doped with diamond or carbon nano-particles to further enhance the thermal conductivity of the heat exchanger 200. In some embodiments, one or more portions of the housing 202 or other portions of the heat exchanger 200 may be secured together via welding or another suitable form of connection. Further, in some embodiments, at least a portion of the heat exchanger 200 may be formed via 3D printing or another suitable manufacturing technique. For example, in some embodiments, the heat exchanger 200 may be produced using a vacuum brazing process by which the heat exchanger 200 is brazed within a vacuum oven.

In some embodiments, the three-fluid heat exchanger 200 comprises a plurality of fluid channels. For example, the three-fluid heat exchanger 200 may include a plurality of coolant channels 204, a plurality of PCM channels 206, and a plurality of air channels 208. In some embodiments, the plurality of channels 204, 206, and 208 may include any of compartments, fins, and tubes containing coolant, PCM, and air respectively. In some embodiments, the plurality of channels 204, 206, and 208 form a repeating fin structure 210. The three-fluid heat exchanger 200 may include a number of inlets and outlets configured to receive and provide said fluids. One or more coolant inlets 212 may be included on the housing 202 for receiving the coolant into the plurality of coolant channels 204 and one or more coolant outlets 214 for providing the coolant externally.

In some embodiments, one or more PCM inlets 216 may be included to receive PCM into the plurality of PCM channels 206. In some embodiments, the PCM inlets 216 may also be used to remove PCM from the plurality of PCM channels 206. In some embodiments, the PCM is contained within the plurality of PCM channels 206 and is not circulated through the three-fluid heat exchanger 200. Accordingly, PCM may not be actively added or removed from the three-fluid heat exchanger 200 during operation. In some embodiments, the PCM inlets 216 may also be used to route one or more sensors into the PCM channels 206, such as, any of temperature sensors, or other sensors, for example, sensors are contemplated that measure a phase percentage of the PCM to monitor a percentage of the PCM that has melted or frozen. A plurality of PCM inlets 216 are shown, but embodiments are contemplated in which fewer PCM inlets 216 are included or a single PCM inlet is included.

In some embodiments, the plurality of air channels 208 are open to allow air to freely pass through the three-fluid heat exchanger 200. Further, in some embodiments, one or more fans 106 may be included in the three-fluid heat exchanger 200. For example, the one or more fans 106 may be disposed in or mounted on the housing 202. In some embodiments, the one or more fans 106 may be configured to circulate air through the plurality of air channels 208. For example, the one or more fans 106 may be disposed on a bottom surface of the repeating fin structure 210 such that ambient air is circulated upward through the plurality of air channels 208. Here, the ambient air may be circulated out of the three-fluid heat exchanger 200 to carry off heat by means of convection and thereby cool the PCM. Alternatively, or additionally, embodiments are contemplated in which the one or more fans 106 may be disposed elsewhere on the three-fluid heat exchanger 200 or external to the three-fluid heat exchanger 200. For example, in some embodiments, a plurality of fans disposed in various different directions may be included to further enhance heat transfer of the three-fluid heat exchanger 200. Further, in some embodiments, that use multiple fans, the fans 106 may be placed in series, parallel, or a combination thereof.

In some embodiments, the one or more fans 106 allow the heat exchanger 104 to be effective in a wider variety of operating environments. For example, the fans allow the PCM to be frozen in environments with relatively high ambient temperatures. In some embodiments, the one or more fans 106 reduce the freezing time of the PCM to thereby increase the laser duty cycle of the laser system 102. For example, freezing the PCM quicker allows the PCM to be available to draw more heat from the coolant such that the laser system 102 can be used for a larger period of time without overheating.

Additionally, in some embodiments, one or more plates 218 may be disposed on a bottom surface of the housing 202, as shown, protruding out past the remainder of the bottom surface of the one or more PCM inlets repeating fin structure 210 beneath the plurality of PCM channels 206. In some such embodiments, the plates 218 further increase heat transfer between the PCM and the surrounding environment to enhance the cooling of the PCM. As such, embodiments are contemplated in which at least a portion of the one or more fans 106 may be configured to circulate air onto the one or more plates 218 to further increase the cooling rate of the PCM. In some embodiments, the one or more plates 218 may include a metallic material such as aluminum or another high thermal conductivity material to facilitate heat transfer between the PCM and the ambient environment.

FIG. 2B illustrates the repeating fin structure 210 separated from the three-fluid heat exchanger 200 relating to some embodiments. In some embodiments, the repeating fin structure 210 includes the plurality of channels 204, 206, and 208 with a perpendicular orientation. For example, the plurality of coolant channels 204 may be oriented in a first direction and the plurality of PCM channels 206 and the plurality of air channels 208 may be oriented perpendicular to the plurality of coolant channels 204 in a second direction. In some such embodiments, the perpendicular orientation of the channels increases heat transfer between the channels. Additionally, embodiments are contemplated in which the channels may be parallel instead of perpendicular with opposite flow directions to increase heat transfer between the PCM, air, and coolant. For example, the plurality of coolant channels 204 may flow in a first direction while the plurality of PCM channels 206 and the plurality of air channels 208 flow in a second direction opposite to the first direction to increase heat transfer and thereby draw more heat out of the coolant.

In some embodiments, at least a portion of the plurality of channels 204, 206, and 208 is defined by a plurality of fins of the repeating fin structure 210. Further, in some embodiments, varying channel widths may be included. For example, the fins of the plurality of coolant channels 204 may have a fin height of about one eighth of an inch and the fins of the plurality of PCM channels 206 and the plurality of air channels 208 may have a fin height of about one fourth of an inch. In some embodiments, a larger fin height of the PCM and air channels 206 and 208 allows for additional capacity of thermal storage from the coolant. Additionally, embodiments are contemplated in which other fin heights and channel widths are included. For example, in some embodiments, the fin heights may be selected from a range of about one sixteenth of an inch to about one inch. However, it should be understood that other fin dimensions outside of this range and not explicitly described herein may also be used.

In some embodiments, the repeating fin structure 210 includes a specific number of channels in each of the pluralities of channels 204, 206, and 208. For example, the repeating fin structure 210 includes thirteen coolant channels 204, thirteen PCM channels 206, and thirteen air channels 208. Additionally, embodiments are contemplated in which any number of channels may be included. Further, in some embodiments, a specific number of fins for each of the plurality of channels 204, 206, and 208 per inch is used. For example, each of the plurality of channels 204, 206, and 208 may include about 8 to 10 fins per inch of width of the repeating fin structure 210. However, embodiments are contemplated in which different numbers of fins and channel widths are contemplated.

In some embodiments, the fins that define the pluralities of channels 204, 206, and 208 include a metallic material such as aluminum an aluminum allow or other type of pure metal or metal alloy with a relatively high thermal conductivity to thereby increase a heat transfer rate between the channels. Further, a high number of fins per inch may increase the heat transfer rate by increasing the exposure to the metal surface of the fins. However, it should be understood that, in some embodiments, other types of materials may be used.

In some embodiments, the repeating fin structure 210 further comprises a plurality of plates 220 separating the pluralities of channels 204, 206, and 208. In some such embodiments, the plates 220 may be composed of a thermally conductive material to facilitate heat transfer between the fluids and/or materials disposed in the channels. For example, the plates 220 may comprise aluminum bus bar. In some embodiments, the plates 220 may be welded to other portions of the repeating fin structure 210.

### Selection of Phase Change Materials

Embodiments are contemplated in which any of a number of phase change materials (PCMs) are used within the heat exchanger system 100. For example, organic PCMs may be used including hydrocarbons such as paraffins, other types of waxes, lipids, sugars, and alcohols or inorganic PCMs may be used such as salt hydrates. Additionally, or alternatively, embodiments are contemplated in which a combination of different PCMs are used. Such as, for example, a mixture organic and inorganic PCMs, or multiple types of organic PCMs. In some embodiments, solid-to-liquid PCMs are used such that the heat produced by the laser system is absorbed as the PCM melts from solid form to liquid form. In some embodiments, solid-to-liquid PCMs are selected among other types of PCMs for the ability to provide cooling without relying on large volume and high-pressure components. Accordingly, the liquid-to-solid PCMs allow cooling while maintaining a small volume footprint as opposed to gas-to-liquid PCMs that typically use large volumes and high-pressure storage. In some embodiments, organic PCMs are selected because organic PCMs work well with various metals (and other materials) that may be used to form the PCM channels. For example, non-organics such as salt hydrates may react with aluminum and lead to corrosion of the PCM channels.

In some embodiments, the type of PCM may be selected based at least in part on the melting and freezing point temperature of the PCM. For example, the PCM may be selected such that the melting point is at or below the operating temperature of the laser system and the freezing point is at or above the ambient temperature of the operating environment. Accordingly, the PCM will begin to melt when the laser system is in use and the PCM will be cooled by providing ambient air from the surrounding environment. In some embodiments, the PCM may be selected such that the freezing point of the PCM is at or above the maximum environmental temperature estimated for the operating environment. Additionally, embodiments are contemplated in which a number of different PCMs with varying melting temperatures ranging across an operating temperature range of the laser system are selected. For example, a mixture of multiple different PCMs may be included within the plurality of PCM channels 206 or different PCMs may be contained within separate compartments of the three-fluid heat exchanger 200.

In some embodiments, a PCM may be selected that has one or more different melting points or freezing point. For example, a PCM is contemplated that has a single melting point but two distinct freezing points. Accordingly, in some cases, the environmental temperature may be below one or both of the two distinct freezing points to preserve the effectiveness of the PCM heat exchanger system.

Additionally, in some embodiments, any of a number of additives or dopants may be incorporated into the PCM to increase the thermal properties of the PCM. For example, high conductivity additives may be added to the PCM to increase the thermal conductivity of the PCM with little to no effect on the density of the PCM to thereby increase the heat transfer rate and reduce the freezing time of the PCM. In one example, high-conductivity nano-materials may be added to the PCM such as, carbon-based nanoparticles or nano-structures, metal-alloy nanoparticles, or non-metal nanoparticles. Additionally, other material additives that are not nano-based may be added to the PCM to enhance the thermal properties. For example, high-conductivity oils or other fluids may be added to or mixed with the PCM to facilitate increased heat transfer to the PCM. It should be understood that material additives may also be added to alter other thermal properties of the PCM. For example, certain additives may be used to alter the melting and freezing temperature of the PCM. Accordingly, said material additives may be used to tune the PCM for a specific operating temperature and/or other environment-specific operating parameters.

### System Control and Power

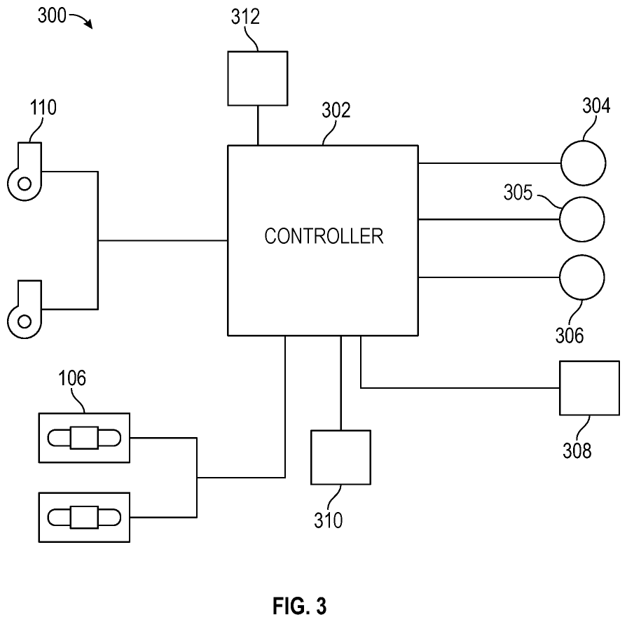

FIG. 3 illustrates an exemplary control system 300 relating to some embodiments. The control system 300 comprises at least one controller 302, as shown. In some embodiments, the controller 302 may be incorporated into either of the laser system 102 or the heat exchanger 104, or in certain embodiments, may be included as a separate component of the system 100. In some embodiments, the controller 302 may comprise at least one processor for processing information and executing one or more operations. For example, the controller 302 may be programmed to perform a number of steps relating to any of receiving and processing one or more signals and adjusting one or more operational parameters of the control system 300. The controller 302 may be communicatively coupled to the one or more fans 106 and the one or more pumps 110. For example, the controller 302 may be coupled to the one or more fans 106 and the one or more pumps 110 such that the controller 302 provides control information to the one or more fans 106 and the one or more pumps 110. In some such embodiments, the controller 302 may be coupled to one or more switches configured to activate, deactivate, and/or adjust the fans 106 and pumps 110.

In some embodiments, the controller 302 is coupled to one or more temperature sensors such as a first temperature sensor 304 disposed on or within the PCM channels of the heat exchanger 104. Alternatively, the first temperature sensor 304 or another temperature sensor may be coupled to the laser system 102 to detect a temperature of the laser system 102. In some embodiments, a second temperature sensor 305 configured to measure an ambient temperature of the heat exchanger system 100 may be coupled to the controller 302. Additionally, in some embodiments, a third temperature sensor 306 may be included for measuring a temperature of the laser system 102. The temperature sensors 304, 305, and 306 may include any of thermocouples, thermistors, resistance temperature detectors, semiconductor-based sensors, or any combination thereof. The third temperature sensor 306 may be disposed within a portion of the laser system 102, such as, in a laser generation portion of the laser system or in a coolant path of the laser system 102. Further, in some embodiments, the third temperature sensor 306 may be disposed in the coolant inlet 212 of the heat exchanger 104 to read the temperature of the coolant from the laser system 102. The second temperature sensor 305 may be included externally on either of the laser system 102 or the heat exchanger 104. In some such embodiments, the second temperature sensor 305 may be at least partially insulated from the heat exchanger 104 and the laser system 102 such that heat from said devices does not interfere with the temperature of the ambient air. Further, in some embodiments, the second temperature sensor 305 may be included within an ambient air inlet of the heat exchanger 104 to detect an ambient temperature of the ambient air entering the air inlet.

Further still, in some embodiments, one or more sensors may be disposed at an outlet of the heat exchanger 104 or laser system 102. In some embodiments, data from a plurality of sensors disposed in different locations across the system 100 may be considered by the controller 302 such that determinations can be made, for example, based on comparisons between the data from different locations.

In some embodiments, the controller 302 receives laser status information 308 from the laser system 102. The laser status information 308 may include an indication of the status of the laser system 102, such as, any of off, on, laser ready, high usage, and other suitable laser system statuses. In some embodiments, the controller 302 instructs operation of the one or more fans 106 and the one or more pumps 110 based at least in part on any of information received from the first temperature sensor 304, the second temperature sensor 305, the third temperature sensor 306, the laser status information 308, or combinations thereof. For example, the fans 106 and pumps 110 may be activated based on detecting an increased laser operating temperature of the laser system 102 using the first temperature sensor 304. Similarly, the fans 106 and pumps 110 may be activated preemptively based on the laser status information 308. For example, the pumps 110 may be activated prior to the laser generation portion being heated based on the laser system 102 being turned on. Further, in some embodiments, the controller 302 may be programmed to adjust the fan speed of the one or more fans 106 based on the temperatures of the PCM or the laser system, the ambient temperature, or comparisons thereof. For example, if the PCM temperature is within a threshold range from the ambient temperature the fan speed may be increased to allow the PCM to be frozen in high temperature operating environments. Similarly, a power level of the one or more pumps may be adjusted, for example, based on a comparison of the laser system temperature and the PCM temperature.

In some embodiments, operation of the one or more pumps 110 and the one or more fans 106 may be adjusted based on comparisons of signals from any of the temperature sensors 304, 305, and 306. Accordingly, the control system 300 may adjust operation of the heat exchanger system based on any of the PCM temperature, the ambient air temperature, and the laser system temperature. For example, in some embodiments, operation of the one or more pumps 110 such as adjustments to the pump power, pump flow rate, or activation/deactivation of the pumps 110, may be controlled based on a comparison of the PCM temperature from the first temperature sensor 304 and the laser system temperature from the third temperature sensor 306. In some embodiments, operation of the one or more fans 106 such as any of the fan power, flow rate, or activation/deactivation of the fans 106, may be controlled based on a comparison of the PCM temperature from the first temperature sensor 304 and the ambient air temperature from the second temperature sensor 305.

In some embodiments, the control system 300 includes one or more PCM sensors 310 operable to detect a percentage of the PCM in the plurality of PCM channels 206 that is melted. For example, the one or more PCM sensors 310 may be disposed on or within the PCM channels 206 to determine an amount of the PCM that is currently melted. Accordingly, operation of the heat exchanger system 100 may be adjusted based on the amount of PCM that is melted. For example, if all or most of the PCM has melted a warning signal may be generated to warn an operator to stop using the laser system 102 to prevent overheating. Further, a notification that the heat exchanger system 100 is ready for use may be transmitted to an operator based on a determination that a significant amount of the PCM is frozen. In some embodiments, the one or more PCM sensors 310 may include a float sensor, a fiber optic sensor, capacitance sensor, a temperature sensor such as described above, or other form of sensor operable to detect a portion of melted PCM within the PCM channels 206.

In some embodiments, the control system 300 may consider correlations between one or more temperatures measured from the coolant or air with one or more temperatures of the PCM. Accordingly, the coolant temperature or air temperature may be used to approximate a portion of the PCM that has melted. In some embodiments, a plurality of temperature sensors may be disposed along the PCM channels to determine a percentage of PCM that has been melted. For example, in some embodiments, the PCM tends to melt from front to back of the PCM channels consistent with the direction of coolant or airflow. Further, embodiments are contemplated in which initial testing and analysis of temperature data throughout the length of the PCM channels may be used to establish correlations of the melting percentage of the PCM with other parameters such that the portion of the PCM that has been melted may be inferred based on other parameters or based on a single temperature measurement taken from a known location within the PCM channels. For example, the correlation of the temperature at a single location within the PCM channels may be used to predict the overall portion of the PCM that has melted based on historical temperature data and melting percentage data obtained from testing the heat exchanger.

In some embodiments, the exemplary control system 300 further comprises at least one power source 312, as shown. In some such embodiments, the power source 312 may be an electrical power source such as a battery. Further, embodiments, are contemplated in which power is received from one or more different sources. For example, power may be received from any combination of one or more batteries, a power cable, a solar panel, or a waste heat recovery system.

In some embodiments, at least a portion of the power for the control system 300 may be received from a waste heat recovery system associated with the laser system 102. In such embodiments, the waste heat recovery system may receive waste heat generated by the laser system 102 and convert the waste heat into electrical energy. For example, one or more Seebeck devices or other forms of thermoelectric device are included that generate electrical energy from heat. Accordingly, the waste heat recovery system may further cool the laser system 102 while also generating energy to power devices of the control system 300. For example, energy generated by the waste heat recovery system may be used to at least partially power the one or more fans 106 and the one or more pumps 110. In some such embodiments, the waste heat recovery system may receive the coolant that is output from the laser system 102 before the coolant is routed to the heat exchanger 104. Alternatively, the waste heat recovery system may be placed directly on or within the laser system 102. Similarly, heat may be recovered alternatively, or additionally, from the heat exchanger as the heat is rejected from the PCM to the ambient air.

Embodiments are contemplated in which the heat exchanger system 100 operates at least partially using passive means. For example, in some embodiments, the amount of controls is reduced by passively controlling operation of the control system 300. For example, one or more thermoelectric devices of the waste heat recovery system may be automatically activated upon receiving heat from the laser system 102 during use such that power may be generated and directed to the one or more fans 106 and the one or more pumps 110 to passively initiate operation of the heat exchanger system 100. In some such embodiments, further passive control may occur, for example, as the temperature of the laser system 102 increases the thermoelectric devices naturally generate more power, which may result in the fan speed or fan power level of the one or more fans 106 being passively increased based on the increase in temperature.

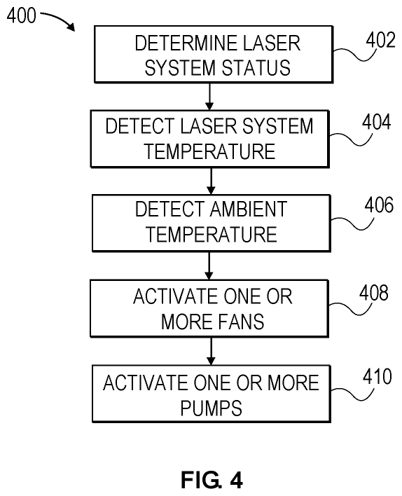

FIG. 4 illustrates an exemplary method 400 of operation for the heat exchanger system 100 relating to some embodiments. In some embodiments, at least a portion of the steps of the method 400 may be carried out on one or more processors, such as, for example, using a processor, microprocessor, or microcontroller included in the controller 302.

At step 402, a status of the laser system 102 is determined. In some embodiments, the status of the laser system 102 may be any of off, ready, operating, high usage, or another suitable laser system status. For example, in some embodiments, an off status is determined when the laser system 102 is disconnected or not being used, the ready status is determined if the laser system 102 is on and ready but not currently firing or actively being used, the operating status is determined if the laser system 102 is being used, and the high usage status may be determined if the laser system 102 is being used in a high power mode or has been used for an extended period of time.

At step 404, a temperature of the laser system 102 is detected. In some embodiments, the temperature of the laser system 102 may be detected using one or more temperature sensors disposed on or within the laser system 102, such as, for example, the first temperature sensor 304. In some embodiments, the laser system temperature may refer to a temperature of the coolant within the laser system 102. Alternatively, or additionally, in some embodiments, the laser system temperature may refer to an internal temperature of the laser system 102. Further, in some embodiments, the status of the laser system 102 may be determined based at least in part on the detected temperature of the laser system 102. Additionally, or alternatively, the laser system status may be determined based on one or more operator inputs, controls, or other sensors disposed on the laser system 102. In some embodiments, the temperature of the laser system 102 may be indicative of operating status of the laser system 102. For example, if the temperature is above an operating temperature threshold it may be determined that the laser system 102 is actively being used or has recently been used.

At step 406, an ambient temperature is detected. In some embodiments, the ambient temperature may be determined using one or more temperature sensors disposed within the operating environment of the laser system 102, such as, for example, the second temperature sensor 305. In some embodiments, the ambient temperature and the laser system temperature may be compared to determine a control routine for the heat exchanger system 100.

At step 408, one or more fans may be activated. In some embodiments, the one or more fans may be activated responsive to comparing the PCM temperature and the ambient temperature. For example, the fans 106 may be activated responsive to determining that the PCM temperature exceeds the ambient temperature or exceeds the ambient temperature by at least a predetermined threshold. Alternatively, or additionally, embodiments are contemplated in which the one or more fans may be activated based on the temperature of the laser system or coolant. Further, the one or more fans may be activated based on a determined or estimated percentage of the PCM that is melted or frozen. For example, the fans may be turned on responsive to determining that a threshold percentage of PCM has melted. Additionally, the fans may be deactivated based on a determination that a predetermined threshold of PCM is frozen.

At step 410, one or more pumps may be activated. In some embodiments, the one or more pumps may be activated responsive to comparing the laser system temperature and the PCM temperature. Similarly, to activation of the one or more fans, the one or more pumps 110 may be activated responsive to determining that the laser system temperature exceeds the PCM temperature or exceeds the PCM temperature by at least a predetermined threshold. In some embodiments, the pumps 110 are configured to pump coolant through the plurality of coolant channels 204 to thereby cool the coolant that exits the laser system 102 by transferring heat to the PCM within the plurality of PCM channels 206.

In some embodiments, besides activating the one or more fans 106 and the one or more pumps 110 operation of the fans and pumps may be further adjusted. For example, embodiments are contemplated in which a power level of any of the one or more fans 106 and the one or more pumps 110 may be adjustive based on any of the laser system temperature, the PCM temperature, percentage of PCM that is melted, and the ambient temperature or comparisons between said parameters. In some such embodiments, the power level of the fans 106 may be increased based on the PCM temperature increasing above a first threshold level and increased yet again if the PCM temperature increases above a higher second threshold level. Alternatively, the fans may be activated or adjusted based on the percentage of PCM that is melted. Further, the speed of the pumps 110 may be increased or decreased responsive to the temperatures.

Additionally, embodiments are contemplated in which one or more pumps may be selectably operated or adjusted based on the temperature of the laser system 102. For example, operation may be switched between a first pump and a second pump to route the coolant through a particular channel or through a selective portion of the plurality of coolant channels 204. In some such embodiments, multiple different PCMs may be used with varying melting point temperatures such that the coolant can be routed to a particular PCM based on the temperature to increase the efficiency of the heat exchanger system 100 in different operating conditions. For example, a plurality of pumps may be configured to pump coolant through portions of the plurality coolant channels that are adjacent to respective PCM channels with different types of PCMs or PCMs with different melting points.

Further, embodiments are contemplated in which at least a portion of the heat exchanger 104 may be removable such that the portion of the heat exchanger 104 may be selectably replaced, for example, to replace the heat exchanger 104 with a second heat exchanger including a PCM optimized to a particular operating environment. Further still, in some embodiments, one or more PCM compartments of the heat exchanger 104 may be removable such that the PCM compartments can be replaced with other PCM compartments based on the ambient temperature or another operating environment or operation parameter. Accordingly, the PCM that is used may be changed without removing the PCM from the plurality of PCM channels 206. Additionally, embodiments are contemplated in which a removable auxiliary chiller may be included. Accordingly, the chiller may be used to expand the range of environments that the heat exchanger system can be used in, such as high temperature operating environments. For example, the auxiliary chiller may be used if an increased ambient air temperature condition is reached. Additionally, the chiller may be removed in other operating environments to reduce the overall weight and power consumption of the heat exchanger system.

In one example, when the laser system 102 is first activated and running at a relatively low temperature the coolant may be routed through a first portion of coolant channels that are adjacent to a first PCM with a relatively low melting point. As the laser system 102 begins running at a hotter temperature, the flow of the coolant may be redirected, for example, by activating different pumps or adjusting one or more valves, to flow through a second portion of coolant channels that are adjacent to a second PCM with a higher melting point. Additionally, or alternatively, in some embodiments, the flow of the coolant may be adjusted based at least in part on the ambient temperature to selectably route the coolant near a PCM that will freeze at or above the ambient temperature.

Although the invention has been described with reference to the embodiments illustrated in the attached drawing figures, it is noted that equivalents may be employed and substitutions made herein without departing from the scope of the invention as recited in the claims.

Having thus described various embodiments of the invention, what is claimed as new and desired to be protected by Letters Patent includes the following:

1. A multi-fluid heat exchanger configured to be coupled to a laser system, the multi-fluid heat exchanger comprising:
a rigid housing;
a repeating fin structure disposed within the rigid housing, the repeating fin structure comprising:
a plurality of coolant channels receiving coolant from the laser system;
a plurality of phase change material (PCM) channels containing one or more PCMs,
wherein the one or more PCMs absorb heat from the coolant and are selected to melt at or below an operating temperature of the laser system and to freeze at or above an ambient air temperature; and
a plurality of air channels receiving air to cool the one or more PCMs; and
one or more fans mounted onto the rigid housing that circulate air through the plurality of air channels to increase a cooling rate of the one or more PCMs.

2. The multi-fluid heat exchanger of claim 1, wherein the plurality of coolant channels is oriented in a first direction, and wherein the plurality of PCM channels and the plurality of air channels are oriented in a second direction perpendicular to the first direction.

3. The multi-fluid heat exchanger of claim 1, wherein the multi-fluid heat exchanger is directly integrated into a housing of the laser system.

4. The multi-fluid heat exchanger of claim 1, wherein the laser system is a laser weapon system that circulates the coolant to cool a laser generation module of the laser weapon system.

5. The multi-fluid heat exchanger of claim 1, wherein the one or more PCMs comprises an organic PCM.

6. The multi-fluid heat exchanger of claim 1, further comprising:
one or more PCM sensors disposed in the plurality of PCM channels, the one or more PCM sensors operable to detect a percentage of the one or more PCMs that is melted.

7. The multi-fluid heat exchanger of claim 6, wherein a notification is transmitted responsive to detecting the percentage of the one or more PCMs that is melted using the one or more PCM sensors if the percentage of the one or more PCMs that is melted is above a predetermined threshold.

8. A heat exchanger system configured to be coupled to a laser system, the heat exchanger system comprising:
a heat exchanger having a rigid housing and a repeating fin structure disposed in the rigid housing, the repeating fin structure comprising:
a plurality of coolant channels receiving coolant from the laser system; and
a plurality of phase change material (PCM) channels containing one or more PCMs,
wherein the one or more PCMs absorb heat from the coolant and are selected to melt across an operating temperature range of the laser system and to freeze at or above an ambient air temperature;
one or more fans coupled to the heat exchanger and configured to cool the one or more PCMs; and
one or more radiators coupled to the heat exchanger to cool the coolant.

9. The heat exchanger system of claim 8, wherein the one or more fans and the one or more radiators are physically separate from the heat exchanger.

10. The heat exchanger system of claim 8, further comprising:
one or more pumps circulating the coolant through the plurality of coolant channels and the one or more radiators,
wherein the one or more pumps are activated based on a comparison between a temperature of the one or more PCMs and a temperature of the laser system.

11. The heat exchanger system of claim 8, wherein the plurality of PCM channels comprises:
a first PCM compartment storing a first PCM, wherein the first PCM is melted at a first temperature within the operating temperature range of the laser system; and
a second PCM compartment storing a second PCM, wherein the second PCM is melted at a second temperature that is above the first temperature and within the operating temperature range of the laser system.

12. The heat exchanger system of claim 8, wherein the heat exchanger is removable from the heat exchanger system such that the heat exchanger may be replaced based on the ambient air temperature.

13. The heat exchanger system of claim 8, further comprising:
a removable auxiliary chiller configured to further cool the one or more PCMs if an increased ambient air temperature condition is reached.

14. The heat exchanger system of claim 8, further comprising:
a battery coupled to the one or more fans, the battery operable to provide electrical power to the one or more fans.

15. A multi-fluid heat exchanger configured to be coupled to a laser system, the multi-fluid heat exchanger comprising:
a rigid housing;
a repeating fin structure disposed within the rigid housing, the repeating fin structure comprising:
a plurality of coolant channels receiving coolant from the laser system;
a plurality of phase change material (PCM) channels containing one or more PCMs,
wherein the one or more PCMs absorb heat from the coolant and are selected to melt at or below an operating temperature of the laser system and to freeze at or above an ambient air temperature; and
a plurality of air channels receiving air to cool the one or more PCMs.

16. The multi-fluid heat exchanger of claim 15, further comprising:
one or more fans mounted onto the rigid housing that circulate air through the plurality of air channels to increase a cooling rate of the one or more PCMs.

17. The multi-fluid heat exchanger of claim 16, further comprising:
a controller programmed to:
receive a first signal indicative of a temperature of the one or more PCMs;
receive a second signal indicative of an ambient temperature;
compare the temperature of the one or more PCMs and the ambient temperature; and
increase a fan speed of the one or more fans based on comparing the temperature of the one or more PCMs and the ambient temperature.

18. The multi-fluid heat exchanger of claim 16, further comprising:
one or more thermoelectric devices that absorb waste heat from the laser system and generate electrical energy,
wherein the electrical energy generated by the one or more thermoelectric devices is used to at least partially power the one or more fans.

19. The multi-fluid heat exchanger of claim 15, further comprising:
one or more plates comprising an aluminum material disposed on a bottom surface of the rigid housing adjacent to the plurality of PCM channels that increase heat transfer between a surrounding environment and the one or more PCMs.

20. The multi-fluid heat exchanger of claim 15, further comprising:
a radiator portion disposed between a fluid connection of the multi-fluid heat exchanger and the laser system, the radiator portion configured to cool the coolant.
